(19) United States
(12) Patent Application Publication
(10) Pub. No.: US 2024/0120888 A1
(43) Pub. Date: Apr. 11, 2024

(54) Semiconductor Integrated Circuit

(71) Applicant: ROHM CO., LTD., KYOTO (JP)

(72) Inventors: Shintaro Matai, Kyoto (JP); Takahiro Kitahara, Kyoto (JP)

(21) Appl. No.: 18/475,804

(22) Filed: Sep. 27, 2023

(30) Foreign Application Priority Data
Oct. 7, 2022 (JP) JP2022162317

(51) Int. Cl. H03F 1/26; H03F 3/45

(52) U.S. Cl. CPC H03F 1/26; H03F 3/45475; H03F 2200/372

(57) ABSTRACT

The present disclosure provides a semiconductor integrated circuit (IC) capable of suppressing influence of disturbance noise. The semiconductor IC includes an input terminal, an amplifier circuit, a first element and a second element. The input terminal is configured to allow inputting a signal of abrupt voltage change. The amplifier circuit is configured to amplify a difference between two input signals. The first element is connected to a first input end of the amplifier circuit. The second element is connected to a second input end of the amplifier circuit. In a plan view, a distance between a first position included in an arrangement region of the first element and a third position included in the input terminal is equal to a distance between a second position included in an arrangement region of the second element and the third position.

### TECHNICAL FIELD

The present disclosure relates to a semiconductor integrated circuit.

### BACKGROUND

Semiconductor integrated circuits (ICs) having various internal circuits are known in the prior art. In particular, among these semiconductor integrated circuits, a semiconductor integrated circuit having an amplifier circuit as an internal circuit (for example, refer to patent document 1 for such amplifier circuit) is available.

### PRIOR ART DOCUMENT

### Patent Publication

[Patent document 1] Japan Patent Publication No. 2020-195075

### BRIEF DESCRIPTION OF THE DRAWINGS

FIG. 1 is a diagram of a configuration of a differential amplifier circuit according to an exemplary embodiment of the present disclosure.

FIG. 2 is a brief diagram of a longitudinal structure of a capacitor formed in a semiconductor integrated circuit.

FIG. 3 is a plan view of an example of a layout of capacitors.

FIG. 4 is a plan view of a variation example of a layout of capacitors.

FIG. 5 is a diagram of a first example of an electrode connection means of a capacitor.

FIG. 6 is a diagram of a second example of an electrode connection means of a capacitor.

FIG. 7 is a circuit diagram corresponding to the first example of an electrode connection means of a capacitor.

FIG. 8 is a circuit diagram corresponding to the second example of an electrode connection means of a capacitor.

FIG. 9 is a diagram of a configuration of a full feedback circuit according to an exemplary embodiment of the present disclosure.

FIG. 10 is a schematic waveform diagram of noise of a main signal and a circuit and external interference noise.

### DETAILED DESCRIPTION OF THE EMBODIMENTS

### 1. Differential Amplifier Circuit

FIG. 1 shows a diagram of a configuration of a differential amplifier circuit 1 according to an exemplary embodiment of the present disclosure. The differential amplifier circuit 1 includes an operational amplifier Op, input resistors R1 and R2, a feedback resistor Rf, a reference resistor Rg, and capacitors Ca and Cb. The differential amplifier circuit 1 is formed in a semiconductor integrated circuit. The operational amplifier Op is an example of an amplifier circuit that amplifies a difference between two input signals.

One end of the input resistor R1 is connected to an end to which an input voltage Vin is applied. The other end of the input resistor R1 is connected to a non-inverting input terminal (+) of the operational amplifier Op. One end of the reference resistor Rg is connected to the other end of the input resistor R1. The other end of the reference resistor Rg is connected to an end to which a reference voltage Ref is applied.

One end of the input resistor R2 is connected to the end to which the reference voltage Ref is applied. The other end of the input resistor R2 is connected to an inverting input terminal (−) of the operational amplifier Op. An output terminal of the operational amplifier Op is connected to one end of the feedback resistor Rf. The other end of the feedback resistor Rf is connected to the other end of the input resistor R2.

In terms of resistance values, R1 equals to R2 and Rf equals to Rg. The input voltage Vin is amplified according to a gain determined by the resistors R1 and Rf, and then is output as an output voltage Vout from an output terminal of the operational amplifier Op.

### 2. Layout of Capacitors

The capacitor Ca is connected between two ends of the reference resistor Rg. The capacitor Cb is connected between two ends of the feedback resistor Rf. A low-pass filter (LPF) is formed by R1 and Ca as well as R2 and Cb.

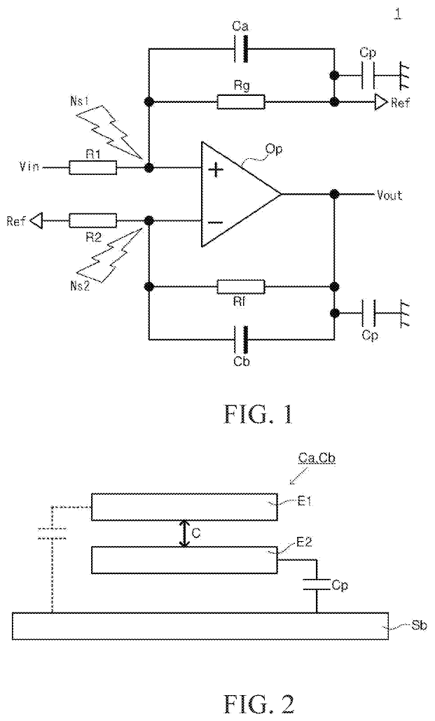

The capacitors Ca and Cb are formed in the semiconductor integrated circuit, and have a longitudinal structure as shown in FIG. 2. The capacitors Ca and Cb have an upper electrode E1 and a lower electrode E2. The lower electrode E2 is formed above a semiconductor substrate Sb. The upper electrode E1 is formed above the lower electrode E2. Main capacitance C is formed between the upper electrode E1 and the lower electrode E2. The upper electrode E1 and the lower electrode E2 are formed of, for example, polycrystalline silicon.

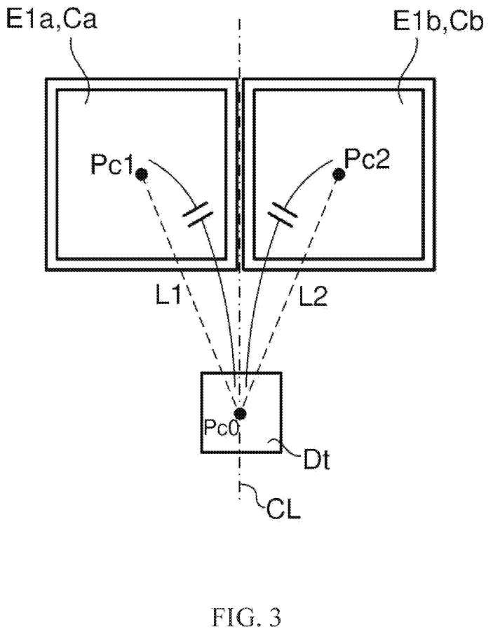

FIG. 3 shows a plan view of the capacitors Ca and Cb when viewed from the top. Thus, respective upper electrodes E1a and E1b of the capacitors Ca and Cb are shown in FIG. 3. Moreover, lower electrodes E2a and E2b are disposed opposite to the upper electrodes E1a and E1b, respectively. Moreover, FIG. 3 depicts a digital signal terminal Dt disposed in the semiconductor integrated circuit. The digital signal terminal Dt is a terminal (solder pad) allowing inputting of a digital signal. The digital signal is an example of a signal of abrupt voltage change.

As shown in FIG. 3, the digital signal terminal Dt and the upper electrodes E1a and E1b are respectively capacitively coupled by, for example, a sealing resin that seals the semiconductor integrated circuit. Accordingly, it is possible that external interference noise is input to the upper electrodes E1a and E1b from the digital signal terminal Dt.

Thus, in this embodiment, a layout of the capacitors Ca and Cb such as that in FIG. 3 is arranged. More specifically, in a plan view when viewed from the top, a distance L1 between a central position Pc1 of the upper electrode E1a and a central position Pc0 of the digital signal terminal Dt is made to be equal to a distance L2 between a central position Pc2 of the upper electrode E1b and the central position Pc0 of the digital signal terminal Dt. Longitudinal positions (positions in the thickness direction of the semiconductor integrated circuit) of the upper electrode E1a, the upper electrode E1b and the digital signal terminal Dt are set to be the same. Moreover, the longitudinal positions of the upper electrode E1a and the upper electrode E1b can also be the same, and these longitudinal positions are different from the longitudinal position of the digital signal terminal Dt.

With such layout of the capacitors Ca and Cb, external interference noise (noise Ns1 and Ns2 shown in FIG. 1) capacitively coupled is input in a same phase to the upper electrodes E1a and E1b and is thus eliminated by the operational amplifier Op.

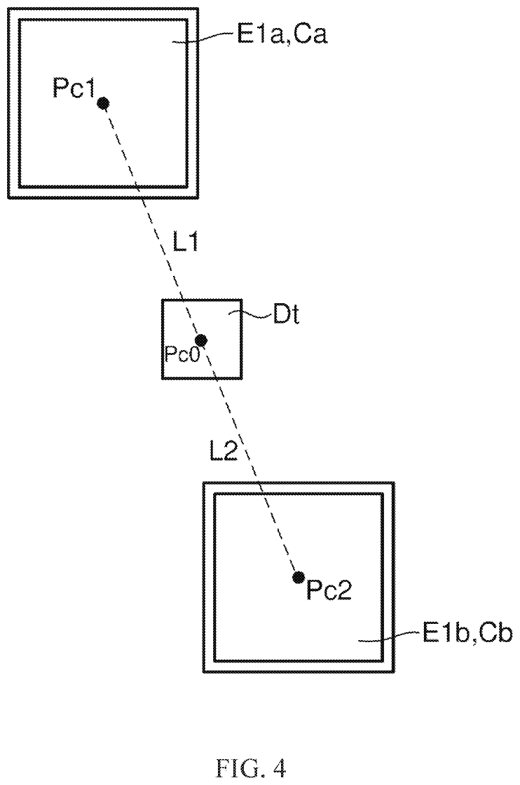

More specifically, in the layout shown in FIG. 3, in a plan view, the central positions Pc1 and Pc2 of the upper electrodes E1a and E1b are in a linear symmetrical arrangement with respect to a central axis CL (a line passing through the central position Pc0) of the digital signal terminal Dt. However, the present disclosure is not limited to the example above; for example, as shown in FIG. 4, in a plan view, the central positions Pc1 and Pc2 can also be in a dot symmetrical arrangement with respect to the central position Pc0. Hence, the distance L1 is also equal to the distance L2.

Moreover, the distance L1 is not necessarily equal to the distance L2 and can differ by 10% offset at most. Even in the case above, an effect of inhibiting influences of 90% of external interference noise can still be achieved.

### 3. Connection Means of Electrodes of Capacitor

In the configuration of the differential amplifier circuit 1 shown in FIG. 1, one end of the capacitor Ca is connected to an input terminal of the operational amplifier Op, which is a high impedance node, and the other end of the capacitor Ca is connected to an end to which the reference voltage Ref is applied, which is a low impedance node. One end of the capacitor Cb is connected to the input terminal of the operational amplifier Op, which is a high impedance node, and the other end of the capacitor Cb is connected to an output terminal of the operational amplifier Op, which is a low impedance node.

The connection means of electrodes of a capacitor include two means below. FIG. 5 shows a diagram of a first example of an electrode connection means of a capacitor. In FIG. 5, the lower electrode E2 is connected to a ground potential (a low impedance node), and the upper electrode E1 is connected to a high impedance node. In this case, as shown on the left of FIG. 7, the upper electrode E1 is connected as a positive electrode.

Herein, as shown in FIG. 2, parasitic capacitance Cp is formed between the lower electrode E2 and the semiconductor substrate Sb. The parasitic capacitance Cp has a capacitance value that is 0.x % to several % of that of the main capacitance C. Moreover, parasitic capacitance (a dotted line in FIG. 2) between the upper electrode E1 and the semiconductor substrate Sb is at a negligible level. As described above, if the upper electrode E1 is connected as a positive electrode, the connection means on the right of FIG. 7 is formed. Since one end of the main capacitance C is connected to the end to which a ground potential is applied, an overall capacitance C′ of the capacitor becomes C. Accordingly, characteristic changes caused by influences of the parasitic capacitance Cp can be inhibited.

Thus, in the configuration shown in FIG. 1, the respective upper electrodes E1 of the capacitors Ca and Cb are connected as positive electrodes, so as to inhibit characteristic changes caused by influences of the parasitic capacitance Cp.

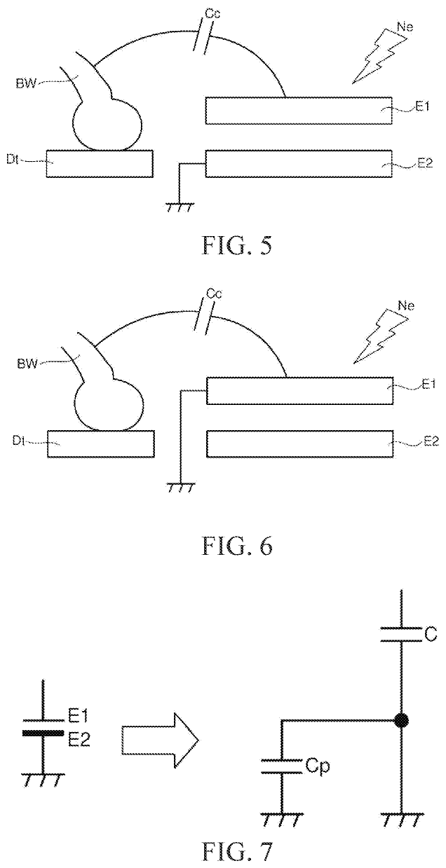

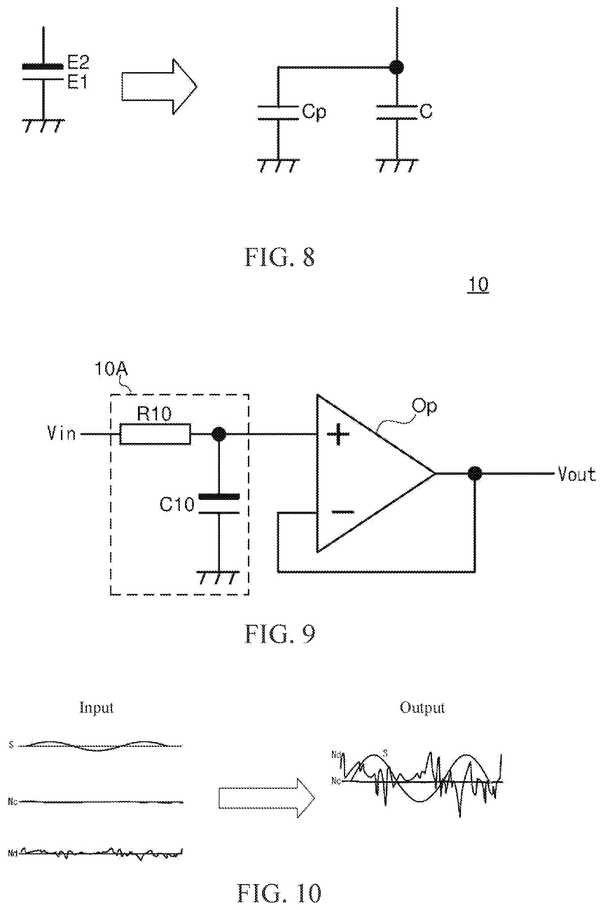

On the other hand, FIG. 6 shows a diagram of a second example of an electrode connection means of a capacitor. In FIG. 6, the upper electrode E1 is connected to a ground potential (a low impedance node), and the lower electrode E2 is connected to a high impedance node. In this case, as shown on the left of FIG. 8, the lower electrode E2 is connected as a positive electrode. Accordingly, a connection means shown on the right of FIG. 8 is formed. Since the main capacitance C and the parasitic capacitance Cp are connected in parallel, the overall capacitance C′ of the capacitor becomes C+Cp.

Herein, as shown in FIG. 5 and FIG. 6, noise capacitively coupled by the digital signal terminal Dt or noise Ne caused by electromagnetic interference (EMI) more greatly affect the upper electrode E1 than the lower electrode E2. Thus, compared to connecting the lower electrode E2 to a low impedance node (an end to which a ground potential is applied) as shown in FIG. 5, by connecting the upper electrode E1 to a low impedance node as shown in FIG. 6, influences of external interference noise can be better inhibited. Thus, as shown in FIG. 8, if the lower electrode E2 is connected as a positive electrode, although characteristic changes caused by influences of the parasitic capacitance Cp are produced, it is more advantageous in respect of inhibiting influences of external interference noise. Moreover, when the digital signal terminal Dt is connected to a bonding wire BW, capacitive coupling Cc includes a capacitive coupling part of the bonding wire BW.

Thus, in the configuration shown in FIG. 1, the capacitors Ca and Cb can also be connected (connecting the electrodes to be opposite to that shown in FIG. 1) such that the lower electrode E2 is a positive electrode. Accordingly, influences of the noise Ns1 and Ns2 can be further inhibited.

Moreover, such connection means of electrodes of a capacitor is not limited to be applied to a circuit having a capacitor group (Ca and Cb) in the layout above (for example, in FIG. 3). For example, a full feedback circuit (a voltage follower) 10 shown in FIG. 9 has the operational amplifier Op and an LPF 10A, and is formed in a semiconductor integrated circuit.

The LPF 10A has an input resistor R10 and a capacitor C10. One end of the input resistor R10 is connected to an end to which an input voltage Vin is applied. The other end of the input resistor R10 is connected to a non-inverting input terminal (+) of the operational amplifier Op. An inverting input terminal (−) of the operational amplifier Op is connected to an output terminal of the operational amplifier Op. An output voltage Vout is generated at the output terminal of the operational amplifier Op.

In the configuration shown in FIG. 9, an upper electrode of the capacitor C10 is connected to an end to which a ground potential is applied (a low impedance node), and a lower electrode of the capacitor C10 is connected to a non-inverting input terminal of the operational amplifier Op (a high impedance node). That is to say, the lower electrode of the capacitor C10 is set as a positive electrode. Accordingly, influences of external interference noise in the full feedback circuit 10 can be inhibited.

### 4. Other

The exemplary embodiments are as described above; however, various modifications may be made to the embodiments without departing from the scope of the subject matter of the present disclosure.

For example, the layout of the capacitors Ca and Cb (FIG. 1) can also be applied to a group including the resistors Rg and Rf. Moreover, such layout is also applicable to a group including the capacitor Ca and the resistor Rf, and a group including the capacitor Cb and the resistor Rg. That is to say, such layout is not limited to being applied to only a group including the same type of elements but is also applicable to a group including different types of elements. However, as a region of an electrode of a capacitor can get wide easily and hence be easily affected by external interference noise, such layout is in particular suitable for a group including capacitors.

Moreover, an amplifier circuit connected to the group including elements of such layout is not limited to being an operational amplifier. In addition, the high impedance node connected to the lower electrode of a capacitor of the connection means above is not limited to being an input end of an amplifier circuit (for example, an operational amplifier).

### 5. Notes

As described above, a semiconductor integrated circuit according to an aspect of the present disclosure is configured as comprising:
an input terminal (Dt), configured to allow inputting a signal of abrupt voltage change;
an amplifier circuit (Op), configured to amplify a difference between two input signals;
a first element (Ca), connected to a first input end of the amplifier circuit; and
a second element (Cb), connected to a second input end of the amplifier circuit, wherein in a plan view, a distance (L1) between a first position (Pc1) included in an arrangement region of the first element and a third position (Pc0) included in the input terminal is equal to a distance (L2) between a second position (Pc2) included in an arrangement region of the second element and the third position (first configuration).

The first configuration may also be configured that, the first position (Pc1) is a central position of the arrangement region of the first element (Ca), the second position (Pc2) is a central position of the arrangement region of the second element (Cb), and the third position (Pc0) is the central position of the input terminal (Dt) (second configuration).

The second configuration may also be configured that, in the plan view, the first position (Pc1) and the second position (Pc2) are arranged symmetrically with respect to a central axis (CL) passing through the third position (Pc0) of the input terminal (Dt) (third configuration).

Any of the first to third configurations may also be configured that, the first element (Ca) is a first capacitor; the second element (Cb) is a second capacitor; the first capacitor includes a first lower electrode (E2a) disposed above a semiconductor substrate (Sb), and a first upper electrode (E1a) disposed above the first lower electrode; the second capacitor includes a second lower electrode (E2b), disposed above the semiconductor substrate, and a second upper electrode (E1b) disposed above the second lower electrode;
the arrangement region of the first element is a region of the first upper electrode; and the arrangement region of the second element is a region of the second upper electrode (fourth configuration).

The fourth configuration may also be configured that, the first upper electrode (E1a) is connected to the first input end, which is a first high impedance node, the first lower electrode (E2a) is connected to a first low impedance node, the second upper electrode (E1b) is connected to the second input end, which is a second high impedance node, and the second lower electrode (E2b) is connected to a second low impedance node (fifth configuration).

The fourth configuration may also be configured that, the first lower electrode (E2a) is connected to the first input end, which is a first high impedance node, the first upper electrode (E1a) is connected to a first low impedance node, the second lower electrode (E2b) is connected to the second input end, which is a second high impedance node, and the second upper electrode (E1b) is connected to a second low impedance node (sixth configuration).

The fifth or sixth configuration may also be configured as further comprising a differential amplifier circuit (1) that includes:
the amplifier circuit (Op), which is an operational amplifier;
a first input resistor (R1), connected to the first input end;
a second input resistor (R2), connected to the second input end;
a feedback resistor (Rf), connected between the second input resistor and an output terminal of the operational amplifier; and
a reference resistor (Rg), connected between the first input resistor and an end to which a reference voltage (Ref) is applied, wherein
the first low impedance node is the end to which the reference voltage is applied, and
the second low impedance node is the output terminal of the operational amplifier (seventh configuration).

Any of the first to seventh configurations may also be configured that, the input terminal (Dt) is a digital signal terminal configured to allow inputting a digital signal (eighth configuration).

A semiconductor integrated circuit according to an aspect of the present disclosure is configured as comprising:
a semiconductor substrate (Sb); and
a capacitor, including a lower electrode (E2) disposed above the semiconductor substrate and an upper electrode (E1) disposed above the lower electrode, wherein
the upper electrode has a lower impedance than the lower electrode (ninth configuration, FIG. 6).

The ninth configuration may also be configured that, the upper electrode (E1) is connected to a low impedance node (tenth configuration).

The tenth configuration may also be configured that, the low impedance node is an end to which a ground potential is applied (eleventh configuration).

Any of the ninth to eleventh configurations may also be configured as further comprising a low-pass filter (10A) including the capacitor (C10) and a resistor (R10) (twelfth configuration).

Any of the ninth to twelfth configurations may also be configured as further comprising an operational amplifier (Op) including an input end to which the lower electrode (E2) is connected (thirteenth configuration).

Any of the ninth to thirteenth configurations may also be configured as further comprising an input terminal (Dt) capacitively coupled to the upper electrode (E1) and configured to allow inputting a signal of abrupt voltage change (fourteenth configuration).

The fourteenth configuration may also be configured that, the input terminal (Dt) is a digital signal terminal configured to allow inputting a digital signal (fifteenth configuration).

### INDUSTRIAL APPLICABILITY

The present disclosure can be applied to a semiconductor integrated circuit having an amplifier circuit formed therein.

1. A semiconductor integrated circuit, comprising:
an input terminal, configured to allow inputting a signal of abrupt voltage change;
an amplifier circuit, configured to amplify a difference between two input signals;
a first element, connected to a first input end of the amplifier circuit; and
a second element, connected to a second input end of the amplifier circuit, wherein
in a plan view, a distance between a first position included in an arrangement region of the first element and a third position included in the input terminal is equal to
a distance between a second position included in an arrangement region of the second element and the third position.

2. The semiconductor integrated circuit of claim 1, wherein
the first position is a central position of the arrangement region of the first element,
the second position is a central position of the arrangement region of the second element, and
the third position is the central position of the input terminal.

3. The semiconductor integrated circuit of claim 2, wherein
in the plan view, the first position and the second position are arranged symmetrically with respect to a central axis passing through the third position of the input terminal.

4. The semiconductor integrated circuit of claim 1, wherein
the first element is a first capacitor,
the second element is a second capacitor,
the first capacitor includes:
a first lower electrode, disposed above a semiconductor substrate; and
a first upper electrode, disposed above the first lower electrode,
the second capacitor includes:
a second lower electrode, disposed above the semiconductor substrate; and
a second upper electrode, disposed above the second lower electrode,
the arrangement region of the first element is a region of the first upper electrode, and
the arrangement region of the second element is a region of the second upper electrode.

5. The semiconductor integrated circuit of claim 4, wherein
the first upper electrode is connected to the first input end, which is a first high impedance node,
the first lower electrode is connected to a first low impedance node,
the second upper electrode is connected to the second input end, which is a second high impedance node, and
the second lower electrode is connected to a second low impedance node.

6. The semiconductor integrated circuit of claim 4, wherein
the first lower electrode is connected to the first input end, which is a first high impedance node,
the first upper electrode is connected to a first low impedance node,
the second lower electrode is connected to the second input end, which is a second high impedance node, and
the second upper electrode is connected to a second low impedance node.

7. The semiconductor integrated circuit of claim 5, further comprising a differential amplifier circuit that includes:
the amplifier circuit, which is an operational amplifier;
a first input resistor, connected to the first input end;
a second input resistor, connected to the second input end;
a feedback resistor, connected between the second input resistor and an output terminal of the operational amplifier; and
a reference resistor, connected between the first input resistor and an end to which a reference voltage is applied, wherein
the first low impedance node is the end to which the reference voltage is applied, and
the second low impedance node is the output terminal of the operational amplifier.

8. The semiconductor integrated circuit of claim 6, further comprising a differential amplifier circuit that includes:
the amplifier circuit, which is an operational amplifier;
a first input resistor, connected to the first input end;
a second input resistor, connected to the second input end;
a feedback resistor, connected between the second input resistor and an output terminal of the operational amplifier; and
a reference resistor, connected between the first input resistor and an end to which a reference voltage is applied, wherein
the first low impedance node is the end to which the reference voltage is applied, and
the second low impedance node is the output terminal of the operational amplifier.

9. The semiconductor integrated circuit of claim 1, wherein the input terminal is a digital signal terminal configured to allow inputting a digital signal.

10. A semiconductor integrated circuit, comprising:
a semiconductor substrate; and
a capacitor, including a lower electrode disposed above the semiconductor substrate and an upper electrode disposed above the lower electrode, wherein
the upper electrode has a lower impedance than the lower electrode.

11. The semiconductor integrated circuit of claim 10, wherein the upper electrode is connected to a low impedance node.

12. The semiconductor integrated circuit of claim 11, wherein the low impedance node is an end to which a ground potential is applied.

13. The semiconductor integrated circuit of claim 10, further comprising a low-pass filter including the capacitor and a resistor.

14. The semiconductor integrated circuit of claim 10, further comprising an operational amplifier including an input end to which the lower electrode is connected.

15. The semiconductor integrated circuit of claim 10, further comprising an input terminal capacitively coupled to the upper electrode and configured to allow inputting a signal of abrupt voltage change.

16. The semiconductor integrated circuit of claim 15, wherein the input terminal is a digital signal terminal configured to allow inputting a digital signal.
